(19) United States
(12) Patent Application Publication
(10) Pub. No.: US 2013/0127029 A1
(43) Pub. Date: May 23, 2013

(54) TWO LEVEL LEADFRAME WITH UPSET BALL BONDING SURFACE AND DEVICE PACKAGE

(71) Applicants: Lee Han Meng @ Eugene LEE, Muar (MY); Wei Fen Sueann LIM, Melaka (MY); Chen Seong CHUA, Melaka (MY); Kooi Choon OOI, Melaka (MY)

(72) Inventors: Lee Han Meng @ Eugene LEE, Muar (MY); Wei Fen Sueann LIM, Melaka (MY); Chen Seong CHUA, Melaka (MY); Kooi Choon OOI, Melaka (MY)

(73) Assignee: TEXAS INSTRUMENTS INCORPORATED, Dallas, TX (US)

(21) Appl. No.: 13/300,189

(22) Filed: Nov. 18, 2011

(51) Int. Cl. H01L 23/495; H01L 21/56

(52) U.S. Cl. 257/675; 257/676; 438/113; 257/E23.042; 257/E21.502; 257/E21.599

(57) ABSTRACT

A leadframe, device package, and mode of construction configured to attain a thin profile and improved thermal performance. Leadframes of this invention include a raised die attachment pad arrange above distal ends of leadframe leads. A package will further include a die electrically coupled with an underside surface of the raised die attachment pad, in one example, using ball bonds, the whole sealed in an encapsulant that exposed a bottom portion of the die and a portion of a lead. Two leadframe stacks of such packages are also disclosed as are methods of manufacture.

### TECHNICAL FIELD

The invention described herein relates generally to semiconductor device packaging and associated leadframes. In particular, the invention relates to cost effective and heat tolerant packages and packaging methods that provide a low package profile and effective heat dissipation when implemented. Aspects of the invention are well suited to multiple leadframe and multi-component electronic packages. The principles herein are also applicable to other semiconductor packages and devices.

### BACKGROUND

Existing packaging solutions for manufacturing electronic devices use a number of packaging technologies. Such devices can use so-called embedded devices that can become quite hot during usage. One way that such devices deal with the heat issues is form a leadless leadframe package that exposes a bottom portion of the packaged die to the ambient environment enabling the heat to be bled off by the ambient. Alternatively, a bottom portion of the die can be exposed and then contacted with a circuit board enabling it to bleed off heat directly into the board. Commonly, in order to achieve such a configuration packages use a leadless leadframe to achieve the desired properties. In such an implementation wire bonds are used to electrically connect input/output (I/O) connectors of an integrated circuit (IC) device with external leads. Although such packaging works well for a large range of devices, it is subject to some limitations.

FIG. 1 illustrates an aspect of a prior art leadless leadframe and some of difficulty that can be encountered with packages using such leadframe configurations. Here, the package 1 includes an integrated circuit die 2 arranged on a die attach pad (not shown in this view) of a leadframe. The die 2 is arranged on the leadframe such that the leadframe periphery includes a set of leads 3. Here, a relatively high density structure having sixty leads 2 is shown. The leads 3 are electrically connected with I/O contacts 4 using wire bonds 5. In small dice with high wire bond density serious difficulties can be encountered during ordinary fabrication. In such high density wire bonding environments a number of package reliability concerns become more concerning. Such high density package environments tend to suffer from increased occurrence of non-sticking second bonds on leads (NSOL), non-sticking bonds on pads (NSOP), wedge bond lift failures, wire bond neck stress, and wire sweep issues.

As used here wire sweep refers to a condition where all the wire bonds are in place and the packaged is prepared for encapsulation. A molding material is injected into a mold space with the rest of the die. The flow of most material can deflect the wires into undesirable configurations leading to a number of failure mechanisms or performance reducing distortions.

Additionally, when wire bonds are formed on top of the die, it is difficult if not impossible to form added components on top of the wire bonds and the IC chip. Thus stacked chip configurations and devices are not well suited to the existing methods of package construction.

For these and other reasons, an improved design of such packages would be helpful in the industry.

### SUMMARY OF THE INVENTION

In accordance with the principles of the present invention, package configurations methodologies are disclosed.

In one embodiment an invention describes an upset leadframe with conductive lower and upper portions. The upper portion has a raised chip mounting pad generally arranged in an upper portion of the leadframe. The raised chip mounting pad includes leads extending from the pad and including a lead that extends away from the raised chip mounting pad and downward into the contact plane. The lead comprises and electrical contact for a die to be mounted with the leadframe.

In another embodiment, the invention describes an integrated circuit (IC) die package mounted with a leadframe. The leadframe comprising a conductive structure with upper and lower portions such that a raised chip mounting pad is arranged in an upper plane and such that the IC die is mounted thereto. The lower portion of the leadframe defines a contact plane into which at least one lead extends. A die is coupled with the raised chip mounting pad, for example, using solder balls, thereby establishing at least one electrical connection between the die and raised chip mounting pad. And such that a bottom surface of the die lies facing downward at the lower portion of the leadframe. A mold envelope is formed encapsulating the die. In some embodiments, another circuit element can be coupled with a top surface of the raised chip mounting pad and also encapsulated.

In some embodiments, a second leadframe is coupled with the IC die. The second leadframe is arranged under the die and under the raised portion of the first leadframe.

Another embodiment describes a method of semiconductor packaging that includes providing a first leadframe with a raised bonding pad and a set of leads extending away from the raised bonding pad such that distal portions of the leads extend below the raised bonding pad to a contact plane. A semiconductor die having electric contacts on a top surface of the die that are electrically coupled with the raised bonding pad. Said mounting further arranged such that the bottom of the die faces away from the raised bonding pad. The die and first leadframe are encapsulated in a mold envelope formed of molding material thereby encapsulating the die in a package so that a bottom portion of the die is exposed at a bottom portion of the encapsulated package and such that at least a portion of the distal ends of said leads are exposed outside the mold envelope.

In another associated method, a second leadframe is mounted with the package such that it is in thermal contact with the bottom of the die. Said packages can also be formed together in large arrays using a common substrate and then singulated to form individuated packages.

These and other aspects of the present invention are described in greater detail in the following detailed description of the drawings set forth herein below.

### BRIEF DESCRIPTION OF THE DRAWINGS

The following detailed description will be more readily understood in conjunction with the accompanying drawings, in which:

FIG. 1 is a plan view of a portion of a known integrated circuit package.

FIGS. 2(a) and 2(b) are perspective views, showing a bottom portion and a top portion of leadframe embodiment having a raised chip mounting pad constructed in accordance with the principles of the invention.

FIGS. 3(a)-3(b) are top plan and side views of a first leadframe embodiment constructed in accordance with the principles of the invention.

FIGS. 4(a)-4(c) are side sectional views of various package embodiments depicted in accordance with the principles of the present invention

FIG. 4(d) is a plan view shown from the bottom up showing a mold cap, a bottom portion of a die, and the leads in accord with an embodiment of the invention.

FIG. 5 is a flow diagram depicting one suitable method embodiment constructing a package embodiment in accordance with the principles of the present invention.

FIGS. 6(a)-6(c) are figurative view of one embodiment of portions of a package fabrication process using a positioning jig in accordance with an embodiment of the invention.

FIG. 7 is a perspective view of an integrated circuit package showing the exposed leads and die attach pad at the bottom of a package embodiment.

FIG. 8(a) is a side cross section view of a dual leadframe integrated circuit package constructed in accordance with an embodiment of the present invention.

FIG. 9 is a plan view of a second leadframe that can be used in an embodiment of a dual leadframe implementation constructed in accordance with the principles of the present invention.

FIG. 10(a) is a plan view of a stacked first and second leadframe illustrating aspects of a dual leadframe implementation constructed in accordance with the principles of the present invention.

FIG. 10(b) is a section view of one embodiment of a pair of leadframes arranged such that when stacked a portion of the first leadframe arranged so that a portion of the second leadframe passes through a raised/lowered portion of the second leadframe.

FIG. 11 is a flow diagram depicting one suitable method embodiment constructing a dual leadframe package embodiment in accordance with the principles of the present invention.

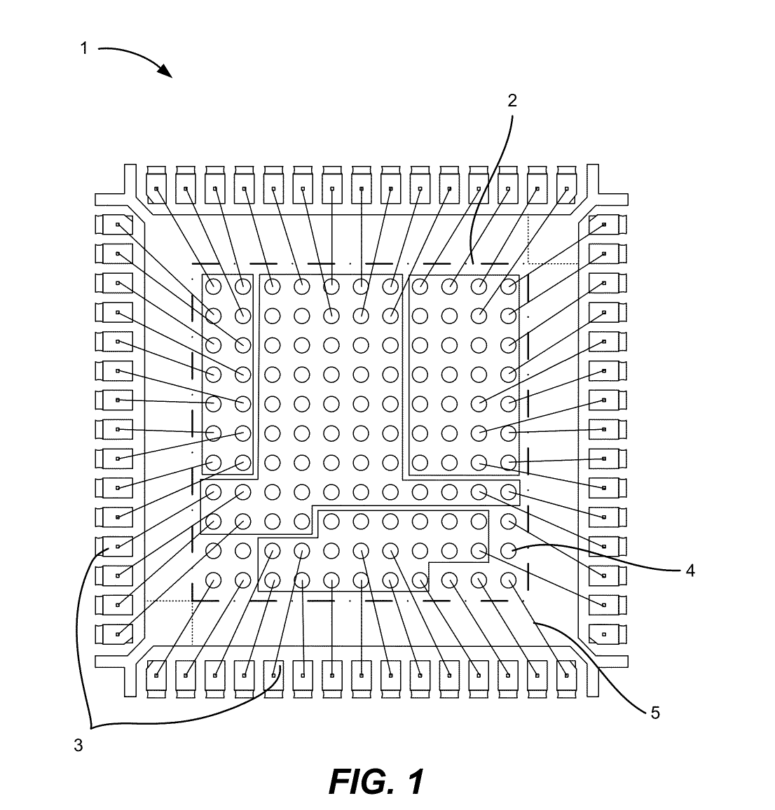

It is to be understood that, in the drawings, like reference numerals designate like structural elements. Also, it is understood that the depictions in the Figures are not necessarily to scale.

### DETAILED DESCRIPTION OF THE DRAWINGS

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the invention.

The following language describes various embodiments of semiconductor packages and construction methodologies. Also described is a related leadframe suitable for use in IC packaging implementations such as those disclosed herein. In particular, the disclosed embodiments describe a raised or up-set leadframe and associated package implementations leading to the construction of a thin profile IC packages. Such packages include, but are not limited to, single and multi-level packages with single of multiple electronic or electrical devices.

The inventors specifically note that the principles of the invention are not limited to such packages, but cover a numbers of related devices as readily apparent to those of ordinary skill

In one implementation, the inventors propose a replacement package and structure for use in many applications. In a particular embodiment, the inventors contemplate the use of a leadframe and package construction of the present invention to replace or augment existing leadless leadframe packages and the inventors contemplate the use of such packages in multi-chip packages, power convertor packages, packages having devices arranged in multiple levels, as well a packages incorporating both passive circuitry as well as active circuitry.

The inventors have briefly pointed out a number of failure modes that plague leadless leadframe packages or packages incorporating high densities of wire bonds. In accordance with many embodiments of the invention a leadframe with raised portion and a lower portion is used to engage both contacts on top of a die as well as provide adequate electrical contact surfaces at a lower portion of the die.

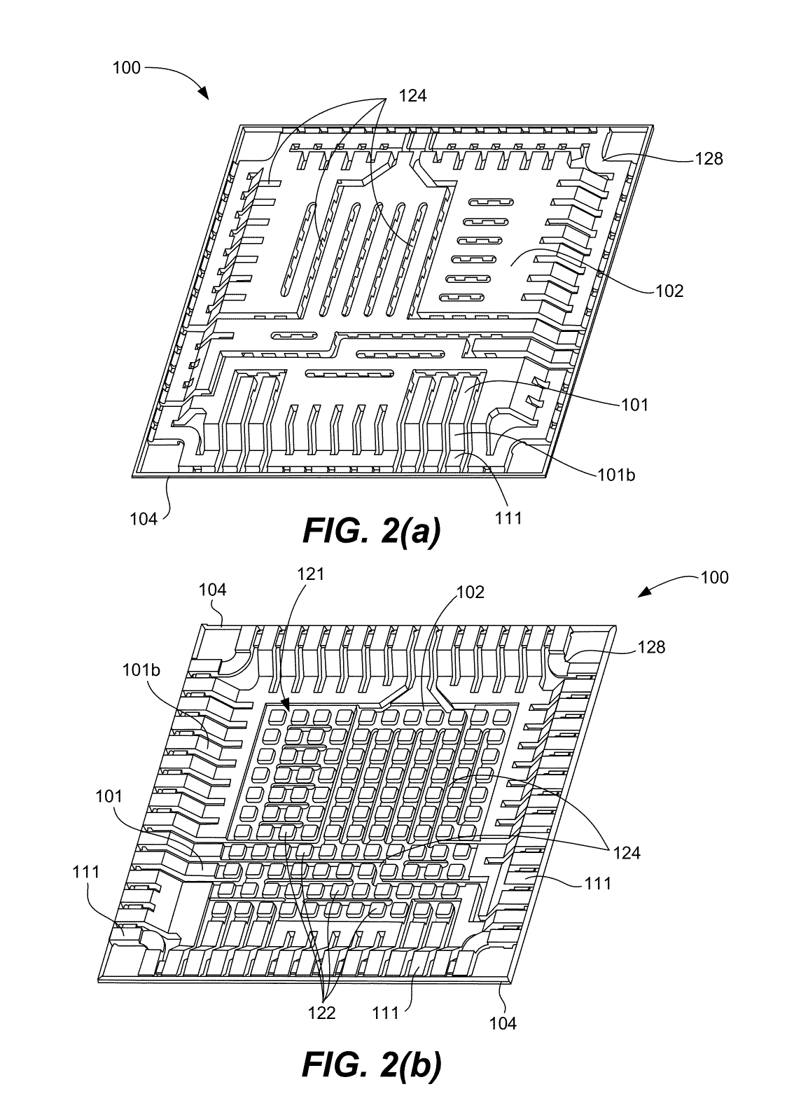

FIG. 2(a) is a perspective view of one example of a suitable upset leadframe 100 as viewed from above the leadframe. FIG. 2(b) is a perspective view of the same leadframe 100 as viewed from below. As referred to herein, such leadframes comprise upset leadframes. Generally, such upset leadframes 100 include an upper portion and a lower portion. Many other configurations and associated embodiments are specifically contemplated by this disclosure.

The leadframe 100 includes an upper portion having a raised chip mounting pad 102 (or raised die bonding substrate) suitable for having a integrated circuit die (or a plurality thereof) mounted thereon. Generally, the raised chip mounting pad 102 has a plurality of leads 101 extending away from the raised portion 102. In this embodiment, a set of leads 101 extend from a centrally arranged raised chip mounting pad 102 such that the leads 101 extend toward the outer edges of the leadframe 100. Importantly, the leads 101 extend downward to the lower portion of the leadframe to form an arrangement of contacts 111 in a different plane than that of the elevated raised chip mounting pad 102. Generally, the raised chip mounting pad 102 is “upset” from the contacts 111 arranged at a lower level.

The inventors particularly point out, that many configurations and arrangements are possible in other embodiments. For example, the raised chip mounting pad 102 can be offset to one side. Also, the leads 101 can extend in many different directions from the raised chip mounting pad 102.

As indicated above, importantly, distal portions of the leads 101 can drop to a lower portion of leadframe 100 to form conductive contacts 111. In some embodiments, the lead 101 configuration can include a bended portion 101 having one, two, or more bended portions that reorient the contact to a second plane that lies below the plane of the raised chip mounting pad 102. In use, the contacts 111 will commonly be electrically connected with other circuit elements, circuit boards, and the like. However, it is also contemplated that the leads 101 and contacts 111 are configured to enable a thermal pathway that enables heat to be directed away from the raised chip mounting pad 101. Typically, the contacts 111 will be located at a distal end of the leads 101. In one embodiment, the leads 101 comprise a downward bend and a second bend arranged to position the contact 111 at the lower portion of the leadframe 100 below the plane defined by the raised chip mounting pad. Although shown here with sixty leads 101, embodiments with more leads or fewer leads are contemplated.

Generally, the leadframe is formed of any conductive material. Copper comprising one suitable leadframe material. However, such leadframes 100 can be formed of other materials or of laminated structures as well as various other types of conductive substrates. In one embodiment having such raised surfaces, the inventors contemplate that a thin metals or a conductive sheet be used to form the leadframe. This thinness will enable the leadframe to be bent into an appropriate shape in an ordinary stamping process. For example, in one implementation the leadframe is constructed of a copper or copper alloy material in the range of about 0.10 mils (2.5 micron (μm) to about 0.20 mils (5 μm) thick. The inventors understand that a leadframe having a thickness of about 0.15 mils thick is suitable many embodiments of the invention.

With reference to FIG. 2(b), the bottom surface 121 of the raised chip mounting pad 102 is shown. Typically, portions of the bottom surface 121 are dedicated to ball attachment sites 122. In simplest form, the ball attachment sites 122 are merely portions of the raised portion 102 of the leadframe with no special attributes other than providing a suitable for electrical contact with other circuit elements. However, in one attractive embodiment, the ball attachment sites 122 are substantially flat surfaces suitable for making good resilient conductive contact with a solder ball. Such ball attachment sites 122 can be made of, or plated with, materials that enhance adhesion (e.g., titanium or other materials). In another related approach, ball attachment sites 122 can comprise raised bonding pads. It should be pointed out that other embodiments can include ball attachment sites arranged on a top surface of the raised portion 102. Generally, the ball attachment sites 122 are used to electrically connect I/O (input/output) connectors of a die with the leads 101. More generally, the ball attachment sites 122 can be used to electrically connect circuit elements with the leadframe 100.

The raised chip mounting pad 102 can further comprise mold flow apertures 124. These apertures can serve several functions. One particularly useful aspect of the features is that during encapsulation of the devices and associated leadframes, the mold flow apertures 124 enable molding material to flow into the encapsulant space in a way that forces air bubbles out of encapsulant space thereby reducing the incidence of defects in the mold cap. Additionally, the mold flow apertures 124 enable encapsulant to flow through the openings and then, upon curing, provide a mechanical locking effect which locks the encapsulant more securely to the leadframe 102 increasing resistance to delamination. This increases the structural integrity of the resultant package and greatly improves the moisture resistance of the associated die, mold cap, and the package as a whole. Such encapsulants are comprised of many materials, including, but not limited to epoxies, plastics, or other molding materials. Typically, these materials are electrically insulative molding materials. Particularly attractive materials include plastics, epoxies, b-stageable materials, low-CTE materials, and any encapsulant and molding materials used by those of ordinary skill to encapsulate electronic packages.

Embodiments of the leadframe 100 can further include a tie bar 104 that temporarily couples the leads 101 and raised portion 102 together on the leadframe 100. Alternatively, more than one tie bar can be used to temporarily couple the leads 101 and raised portion 102 to the leadframe 100. Once the leadframe 100 is assembled and encapsulated, the tie bars can be easily cut away or otherwise removed during singulation or in another post encapsulation process.

Additionally, embodiments of the leadframe 100 can include alignment features 128 for securing the leadframe 100 to a mounting jig. For example, these features can include, but are not limited to, one or more holding arms 128 or apertures arranged on the leadframe to attach the leadframe to a mounting jig. The secured leadframe can enable effective mounting of a die onto the leadframe 100, effective alignment and ball bonding, effective alignment with other leadframes of a leadframe stack, effective encapsulation to form the final package, and so on. In the embodiments depicted in FIGS. 2(a), 2(b). 3(a) & 3(b) (as well as others), a leadframe 100 is shown with securement features configured as four holding arms 128. More (or fewer) such features 128 can be added in accordance with the needs of the associated leadframe. One particularly common approach is to include an alignment feature comprising an aperture formed on a portion of the leadframe such that when the aperture is aligned with a complementary feature of a mounting jig, the frame is in correct orientation and alignment for further processing. As will be apparent to those of ordinary skill, many different configurations of securement and alignment features can be employed to enable the frame to be secured to a mounting fixture or jig. It is pointed out, that depending on the type of alignment features one or many such features (and complementary features) can be used to enable the leadframe to be secured to a mounting jig.

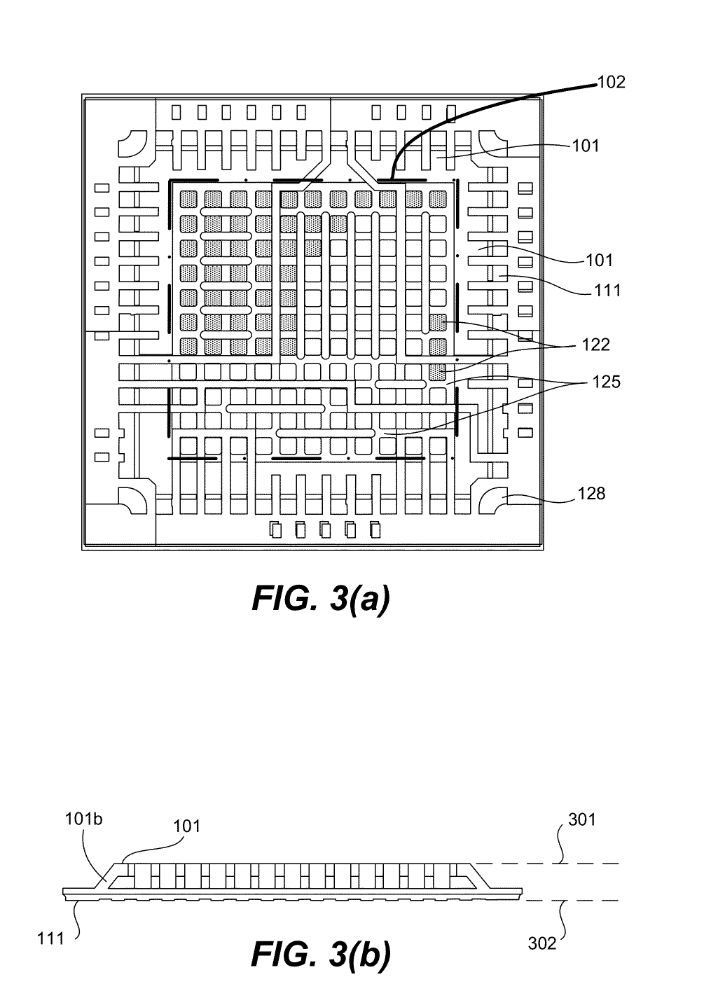

FIG. 3(a) shows a plan view of a portion of the leadframe 100 as viewed from underneath the leadframe 100. Clearly visible is the relationship between the raised chip mounting pad 102 and leads 101 and contacts 111 as well as the ball attachment sites 122. In this embodiment, the ball attachment sites 122 comprise raised features suitable for ball bonding surrounded by lowered portions called here moats 125. The moats 125 are arranged adjacent to the ball attachment sites 122. The moats 122 define a depressed region around each ball attachment site 122 generally arranged to prevent the flow of solder from one ball attachment site 122 to another thereby unintentionally shorting two solder ball connections together. Generally, the moats 122 a formed by etching portions of the raised chip mounting pad 102. Other methods of generating the recessed moats can be used. For example, in one case, selective masking of the leadframe (for example masking the moat portions to leave the ball attachment sites unmasked) and then electroplating the leadframe can also be used to build up the ball attachment sites 122 leaving the masked portion to comprise the moats. In one example a 0.15 mil thick leadframe 100 has a half etched set of moats 125 etched about 0.075 mils deep into the raised portion 102 of the leadframe 100. It is pointed out that ball bonding sites 122 are also often referred to a ball bond pads. The ball bonding sites 122 can be of any size and dimension but are commonly square-shaped having a size on the order of the size of the solder balls used. In one example, bonding site 122 having a dimension of about 100 microns on a side is used. But such bonding pads can range from about vastly over any size range. Suitable moats can also be of any be any size. Typically, such moats are etched to half the depth of the leadframe but there is no requirement to do so. In this embodiment, the depicted moats are about 50 micron wide.

FIG. 3(b) is a cross-section view of the leadframe 100. Clearly visible is the raised chip mounting pad 102 arranged in an upper portion of the leadframe thereby defining an associated upper plane 301 of the leadframe 100. Also shown is the relationship between the raised chip mounting pad and the contacts 111 arranged at the lower portion of the leadframe 100. The contacts 111 depicted in this embodiment are arranged at a distal end of leads 101 (including 101b) extending below the raised chip mounting pad 102 in a second lower contact plane 302. Also shown are the bent portions 101b of the leads 101 that direct the distal ends of the leads downward to form the contacts 111 at the lower portion of the leadframe 100.

The upper portion of the leadframe 100 generally describes the portion of the leadframe that includes the raised chip mounting pad 102. The lower portion being generally defined by the contact 111 portion of the leads 101 that lie significantly below the raised chip mounting pad 102. The distance between the upper plane 301 and the lower plane 302 can be of any distance convenient to the user. Convenient embodiments use a distance between the upper plane 301 and the lower plane of on the order of the height of the die that incorporates the leadframe 100. Generally, the top of the die will be in close physical proximity and electrical contact with the lower surface of the raised chip mounting pad 102 and the underside of the die will lie generally in the plane of the contacts 111. Thus, the heights are roughly on the order of the die to be used with the leadframe 100. In one example, the raised portion is about 0.3-0.8 millimeters above the contacts. In some cases this can result in very compact packages having a height of less than 1 mm high.

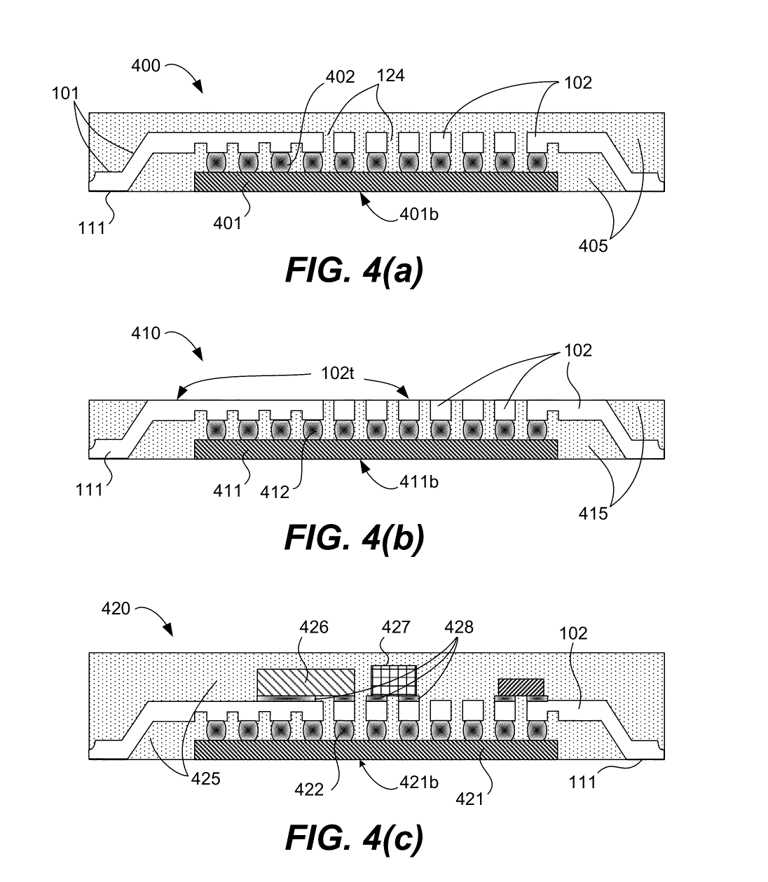

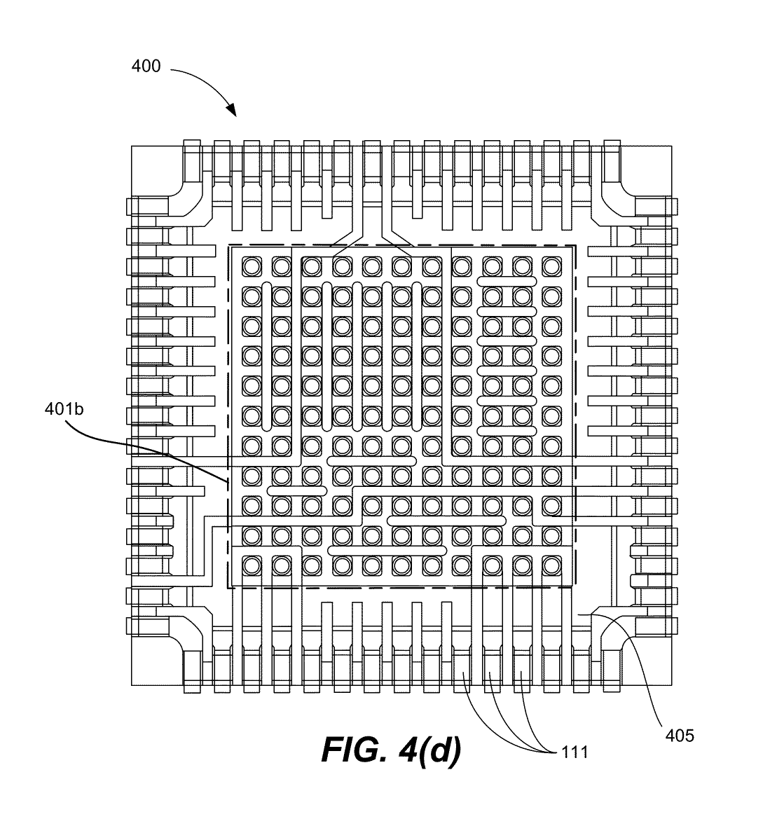

The cross-section views of FIGS. 4(a)-4(d) depict a few embodiments of packages constructed in accordance with the principles of the present invention.

For example, FIG. 4(a) depicts one embodiment of a package 400 using an upset leadframe 100 such as previously described. In such a package 400 an integrated circuit die 401 is electrically connected with a raised chip mounting pad 102 of an upset leadframe using solder balls 402. The solder balls 402 electrically connect electrical contacts on top of the die 401 with the leadframe 100 (e.g., at the ball attachment sites 122). Generally, die I/O contacts on top of the die 401 are electrically coupled with the leads 101 (and hence contact 111) of leadframe 100 to provide electrical connects at the bottom of the die 401. Such contacts can also include grounds as well as all manner or required electrical connections. In this embodiment, the die 401 and leadframe 102 are encapsulated in a mold cap 405 made of encapsulant material. Moreover, in this embodiment, the leadframe 100 is embedded by an encapsulant material 405 forming a mold envelope. In this particular embodiment, the encapsulant material 405 completely encases the upset portion of the leadframe (raised chip mounting pad 102) and exposes the bottom portions of the contacts 111 and the bottom surface of the die 401 (generally, the die attach surface 401b). Also, the encapsulant is shown flowing through the mold flow apertures 124 which upon curing also serve as mold locks that help secure the encapsulant, leadframe, and die together. Such a configuration creates a compact low profile package. Embodiments of any height can be formed without limitation. In one embodiment, a package having a height in the rand of 0.6-0.8 mm can be used. Such mold envelopes can be formed using a wide range of encapsulants. Typically, these materials are electrically insulative molding materials. Examples, include, but are not limited to, plastics, epoxies, b-stageable materials, low-CTE materials, and any other suitable encapsulant and molding materials used by those of ordinary skill to encapsulate electronic packages.

The cross-section view of FIG. 4(b) depicts another embodiment of a package 410 using, for example, an upset leadframe 100 such as previously described. In such a package 410 an integrated circuit die 411 is electrically connected with a raised chip mounting pad 102 of an upset leadframe 100 using solder balls 412. The solder balls 412 electrically connect electrical contacts on top of the die 411 with the leadframe 100 (e.g., at the ball attachment sites 122). The die 411 and leadframe 102 are also encapsulated in a mold cap 415 made of encapsulant material. In this embodiment, an upper surface 102t of the leadframe 100 (i.e., that surface on an opposite side of the die mounting surface upon which the die 411 is mounted) is exposed by the mold cap 415. Thus, the top surface 102t can be exposed to the ambient or selectively coupled with a heat spreader to enhance cooling properties of the package 410. In this particular embodiment, the encapsulant material 415 an upper portion of the leadframe (e.g., a portion of the raised chip mounting pad 102) and also exposes the bottom portions of the contacts 111 and generally the bottom surface of the die 411 (generally, the die attach surface 411b). Such a configuration creates a compact low profile package with enhanced thermal properties.

The cross-section view of FIG. 4(c) depicts another embodiment of a package 420 using, for example, an upset leadframe 100 such as previously described. In such a package 420 an integrated circuit die 421 is electrically connected with a raised chip mounting pad 102 of an upset leadframe 100 using solder balls 422. The solder balls 422 electrically connect electrical contacts on top of the die 421 with the leadframe 100 (e.g., at the ball attachment sites 122). In an added feature, the leadframe 102 further supports one or more additional circuit elements 426, 427 on an upper surface of the leadframe. The elements 426, 427 can comprise any type of circuitry including active circuit elements. However, more commonly, the circuit elements 426, 427 comprise passive circuitry. These elements can be electrically coupled with the leadframe 102 (or the die 421) using any of a number of methods. However, in one particularly useful embodiment, the circuit elements 426, 427 are coupled with the leadframe 100 using a solder paste material 428. Either the leadframe 102 or the circuit element (426, 427) is treated with a solder paste material 428 which is then reflowed to couple the circuit elements 426, 427 to the leadframe 102.

The die 411 and leadframe 102 and other circuit elements 426, 427 are encapsulated in a mold cap 425 made of encapsulant material. In this embodiment, the upper portions of the leadframe 100 and the circuitry 426, 427 can be covered by the mold cap 415. As before, the encapsulant material 425 also exposes the bottom portions of the contacts 111 and generally the bottom surface of the die 421 (generally, the die attach pad 421b). Such a configuration creates a compact low profile package with a large number or systems formed in a discrete package.

By way of quick summary, FIG. 4(d) is a plan view shown from the bottom of an assembled package embodiment (for example, that of FIG. 4(a)) 400 having an encapsulant mold cap 405, an exposed bottom surface 401b of a die 401, and the bottom surfaces of associated leads 111 in accord with an embodiment of the invention.

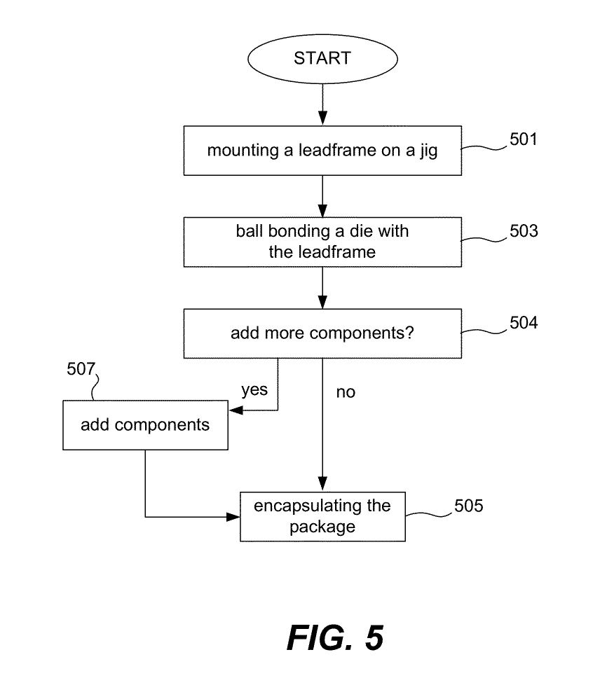

FIG. 5 expresses one typical process for forming such packages. The process begins by providing a leadframe. Commonly, this will be accomplished by stamping out the leadframes from a thin sheet of conductive material and then providing them for use. In one example, a 15 mil thick sheet of copper can be stamped into an appropriate configuration using standard stamping processes known to those having ordinary skill in the art. Other conductive materials or layered substrates can be used as well. For example, a leadframe having a raised chip mounting pad and a series of leads can be formed. For clarity, it is now stated that leads may include bonding pads, ground leads (optionally having a raised portion), and I/O leads (also optionally having a raised portion) and other structures. In one example, a copper sheet can be stamped to form the leadframe in accordance with the principles of the invention. Importantly, and commonly, the leadframe can be formed on a substrate mounting many such leadframes. Tie bars can be employed to maintain features of the leadframes in place during processing. Such leadframe substrate and tie bar implementations are known in the art.

Thus, importantly, the provided leadframe comprises a raised chip mounting pad is provided. Commonly, the leadframe will be arranged on a mounting jig for further processing (Step 501). For example, a securement feature of the leadframe is engaged with a complementary alignment feature of the jig to correctly position and securely hold the leadframe in a desired orientation. Typically, a sheet of material having a plurality of leadframes formed thereon will be arranged on a jig in readiness for further processing.

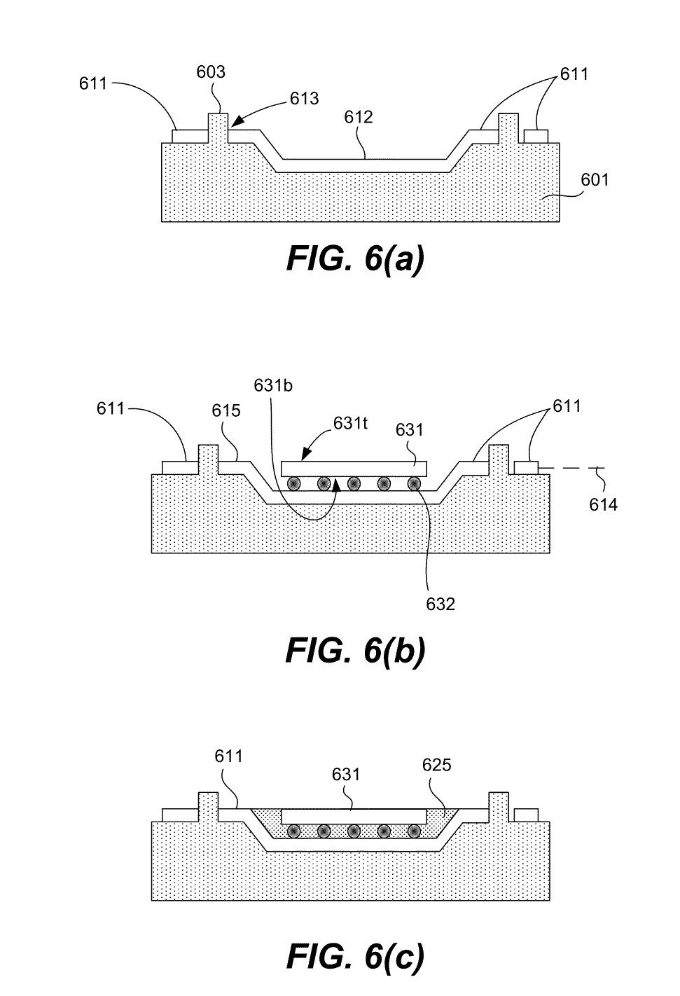

One simplified example of this operation is figuratively illustrated and described with respect to FIG. 6(a). A leadframe 611 is arranged on mounting jig 601 for further processing. Although depicted here as a single leadframe 611, typically a substrate comprising a plurality of leadframes arranged on a single substrate is used. The leadframe 611 includes a raised chip mounting pad 612. Here the leadframe 611 is shown mounted “upside down” on the jig 601. In this implementation, a securement feature 613 of the leadframe 611 is engaged with a complementary alignment feature 603 of the jig 601. For example, the securement feature 613 of the leadframe 611 can simply be one or more holes arranged in the leadframe 611. The complementary alignment features 603 of the jig 601 can simply include a complementary set of members (e.g., pegs) arranged to snugly fit the holes of the leadframe 601. The whole arrangement being engineered such that the leadframe 601 attains a desired alignment on the jig 601. It is specifically pointed out that the use of such a mounting jig is not required but is helpful in many embodiments.

The process continues by mounting an integrated circuit die 631 (or other electronic package) on the leadframe (Step 503). Commonly, this will be accomplished by placing a plurality of solder balls 632 on a bottom surface of the leadframe 611. Such can be used to interconnect the die 631 with the leads and other bonding surfaces of the leadframe 611. For example, the solder balls can be formed to interconnect with at least one of I/O leads, ground leads, heat flow paths and other surfaces of the leadframe. Typically, the solder balls will be placed on the ball attachment sites of the leadframe which are treated to for suitable solder ball bonding surfaces. As an alternative, the solder balls could be arranged on the die 631 prior to mating with the leadframe.

Then, the die 631 can be paired up with leadframe 611. This could be accomplished using several different methods. For example, a pick and place machine can be used to position the die 631 relative to the leadframe 611. One example of such an SMT (surface mount technology) “pick and place” machine is a Model 830 Pick and Place System produced by Semiconductor Equipment Corporation or an X Siemens SIPLACE 80-S20 PCB on-sent machine manufactured by Siemans AG, as well as many others.

In general, the die 631 is mounted with the top die surface 631t facing toward, and electrically connected with, the leadframe 611. The combination of the die 631, solder balls 632, and leadframe 601 are then subject to reflow to mount the die 631 with the leadframe 601. The raised chip mounting pad 612 can be set at a number of heights relative to the lower contact plane 614. The height can vary depending on the needs of the package design. However, in a preferred embodiment, the height of the raised chip mounting pad 612 is such that when the die 631 is mounted with the solder balls 632 to the pad 612 and subject to reflow, the bottom surface of the die 631b can lie in substantially the same plane (614) as the bottom surface of the leadframe 611 (particularly, the bottom surface of the leads 615). Of course, other embodiments can be arranged with the bottom of the leadframe protruding from the completed package or alternatively recessed within the leadframe and covered with an encapsulant such that it is not exposed by the package.

Depending on the nature of the final embodiment, slightly different processes are taken. The design determination indicates the further process steps (Step 504).

The leadframe 611 and associated ball bonded elements, leads, and other contacts are then treated with encapsulant material 625 to seal the die and ball bonds and portions of the leads (Step 505). Such an encapsulation process can accomplished using any of a number of well known encapsulation process known to a person of ordinary skill in the art. Although shown here as encapsulated in place on the jig, such need not ne the case and encapsulation can be performed elsewhere, for example at a mold tool. To continue, one embodiment of an encapsulated package is shown in FIG. 6(c) (which is substantially similar to that of FIG. 4(b)). In the depicted embodiment, the leadframe is encapsulated with the top of the leadframe exposed. Although an embodiment such as shown in FIG. 4(b) can also be fabricated. It should be pointed out that such encapsulation is generally performed using a mold but can in some cases (as shown here) be performed on a jig or using another encapsulation mode.

Additionally, in some embodiments, additional circuit elements are formed on the top surface of the leadframe (Step 507). One such embodiment is shown, by way of non-limiting example, in FIG. 4(c). In one approach, the first die (e.g., 421) can be mounted with the leadframe (e.g., 102) and then the leadframe is flipped over in a flip chip process and the additional circuit elements are applied. Such components (426, 427) can be of any type, but find particular utility with passive components. The ancillary components (426, 427) can also be ball bonded with the top surface of the leadframe, although wire bonding and other conductive attachment methods can be used. Such components can also be subject to reflow to complete the ball bonding process. It is possible to mount the components (426, 427) prior to the first die 421 as well as the reverse. Once the additional components (e.g., 426, 427) are mounted with the leadframe 102, they can be encapsulated (Step 505).

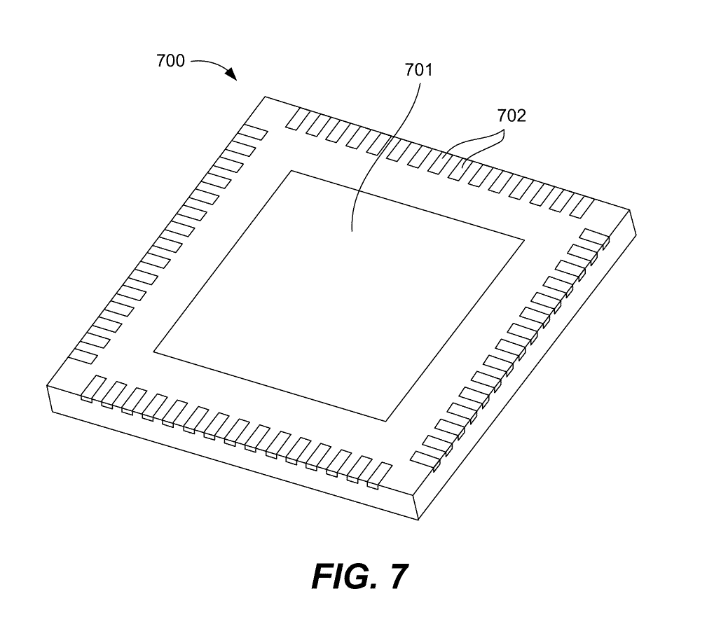

Once the encapsulant is cured and appropriately hardened, the packages can then have the temporary tie bars (such as are used in leadframes) removed from the leads to enable separate connection of the leads. Typically, such tie bar removal is facilitated by the singulation of the packages from a substrate comprising many such packages. The tie bars are typically arranged in the saw streets used to singulate the packages. Thus, in the process of cutting the substrate into separate packages the tie bars are generally removed. One example of a resulting package is shown in FIG. 7. In this view, the mold cap of the package 700 is clearly shown as is the exposed bottom portion 701 of the die and the peripheral leads 702.

The inventors point out that many of these process operations can be performed in any order or, alternatively, be performed together. The completed package, due to the presence of the encapsulant filled mold flow apertures is capable of performing at better than the JEDEC Moisture Sensitivity Level 3 standard. In fact embodiments of the devices disclosed here can perform at the JEDEC Moisture Sensitivity Level 1 standard.

Such packages can exhibit improved electrical performance through the use of ball bonds. Additionally, the extensive use of ball bonds overcomes many of the difficulties inherent in prior art wire bonding processes. Additionally, the thermal performance of such packages is excellent with the large exposed pad at the bottom. Additionally, with exposed leadframe arrangements (e.g., as shown in FIG. 4(b)) still greater thermal performance can be achieved.

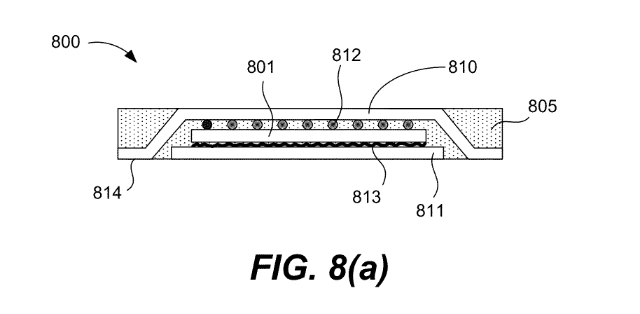

Although disclosed generally as a single leadframe device other packages can be formed. For example, reference is now made to FIG. 8 which is a cross section view of a two leadframe embodiment of a package assembly 800.

In the embodiment of FIG. 8(a) a two leadframe package 800 is shown with an “upset” first leadframe 810 such as previously described with the raised chip mounting pad. As before, an integrated circuit die 801 is electrically connected with a raised chip mounting pad of first leadframe 810 using solder balls 812. The solder balls 812 electrically connect electrical contacts on top of the die 801 with the leadframe 810 (for example at the ball attachment sites 122 such as described elsewhere herein). As before, the upper die contacts are electrically coupled with the leads of leadframe 810 to provide electrical contacts 814 at the bottom of the package 800.

Additionally, a second leadframe 811 is coupled with the bottom side of the die 801. Such can also be done using solder balls. However, in a preferred embodiment, a layer of solder paste 813 can be used instead to electrically and thermally couple the die 801 with second leadframe 811. The assembled entirety is encapsulated in a mold cap 805 made of encapsulant material such as already described.

Here, in this depicted embodiment, the upper surface of the raised chip mounting pad of the first leadframe 810 is exposed at a top of the pad similar to the embodiment shown in previously described FIG. 4(b). Additionally, a bottom surface of the second leadframe 813 is exposed at a bottom of the package providing, among other things a large exposed bonding pad for the package as well a large thermal surface that can be used as a heat spreader to transfer heat away from the package onto a surface onto which the package 800 may be mounted. Accordingly, the bottom pad 811 can operate as a heat spreader.

As before, similar materials, as previously described, can be used in the formation of these second leadframes 811 (i.e., conductive materials including, but not limited to copper leadframes) and encapsulants. Similar low profile stacked leadframe embodiments can be constructed in this way.

Another embodiment illustrates a particular two leadframe package with a first leadframe such as previously described with the raised chip mounting pad. As before, an integrated circuit die is electrically connected with the raised portion of the first leadframe using solder balls. The solder balls electrically connect the die with the leadframe (for example at the ball attachment sites 122 such as described elsewhere herein). As before, the leads of the leadframe extend to provide electrical contacts 864 at the bottom of the package.

The first leadframe has a ground tab that is electrically coupled with a ground contact of the die. As before, such coupling can be done with solder balls or other electrically conductive methods. In this view, a few examples of mold flow apertures are shown.

Additionally, a second leadframe is coupled with the bottom side of the die. Such a second leadframe can also be used to electrically couple the completed package with other substrates or elements and can also function as a heat spreader. To continue, the die can coupled with the second leadframe using a number of modes including solder paste, solder balls, or other approaches.

Importantly, when the second leadframe is coupled with the die it can also be coupled with the first leadframe via the ground tab. The tab can be coupled with the second leadframe commonly using solder paste or ball bonding. However, wire bonding and other interconnection processes can also be used. The tab is electrically connected with a ground connection of the die, thereby defining an electrical path between a ground contact on top of the die, through the first leadframe, and down to the second leadframe. Such a configuration enabled grounding of the die to a substrate using the large pad provided by the bottom surface of the second leadframe. This assembly can be encapsulated in a mold cap made of encapsulant material such as already described, for example, with respect to FIG. 4(a).

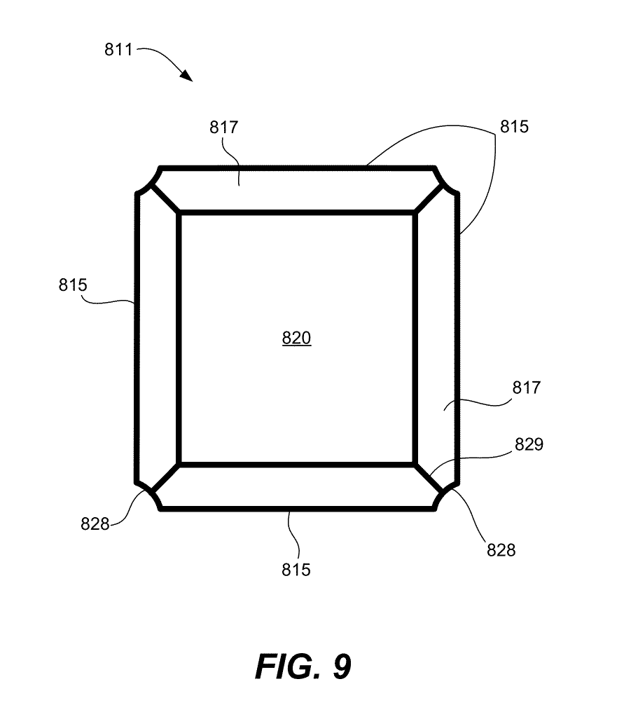

FIG. 9 is a plan view of one example of a suitable second leadframe 813 embodiment. The second leadframe 811 typically includes a die attachment pad 820 (heat spreader) arranged for attachment to the die (e.g., 801). Commonly the pad 820 is centrally located on the leadframe 813, but can be offset as well. Also, the second leadframe 811 can include a set of one or more tie bars 815 arranged to support and position the die attachment pad 820 or other features.

Additionally, embodiments of the second leadframe 811 can include alignment features 828 for securing the leadframe 811 to a mounting jig. For example, these features can include, but are not limited to, one or more holding arms 828 or apertures arranged on the leadframe to attach the leadframe to a mounting jig. In this embodiment, each holding arm 828 has an extension 829 that extends the holding arm away from the pad 820. The reader is reminded that this is just one possible implementation with many other permutations and configurations contemplated by the inventors. As with the first leadframe, when the second leadframe is secured to the jig, it can enable effective mounting of a die with the second leadframe 811, effective alignment and solder paste layer formation (or ball bond attachment), effective alignment with the first leadframe of a leadframe stack, effective encapsulation to form the final package, and so on. In this embodiment, the second leadframe 811 is shown with four holding arms 828 although more (or fewer) features 828 can be added in accordance with the needs of the associated leadframe. As before, other approaches may make use of alignment features comprising a plurality of apertures formed on portions of the leadframe such that when the aperture is aligned with a complementary feature of a mounting jig, the frame is in correct orientation and alignment for further processing. Just as described above, a mounting peg of a jig can be arranged to engage the securement features of both the first and second leadframes to provide a correctly aligned stack.

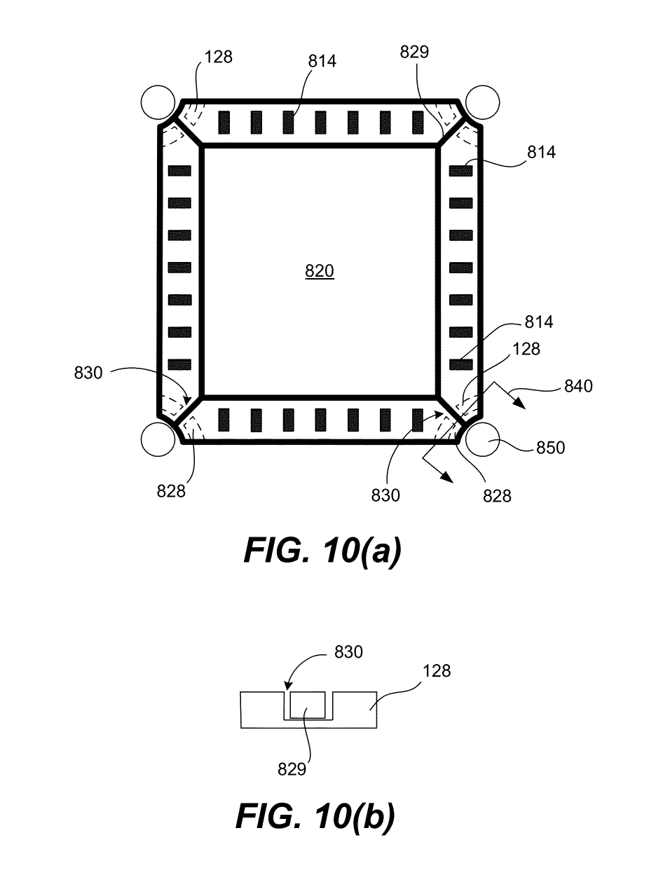

It is also pointed out that in this embodiment, a lead space 817 is provided such that when the first leadframe 810 is stacked with the second leadframe 811, the leads 814 of the first leadframe can lie within the lead space 817 (See, FIG. 10(a)). Here, the lead spaces 817 lie between the pad 820 and the associated tie bars 815. The leads 814 of the first leadframe 810 are arranged such that when the first and second leadframes (810, 811) are mounted on the jig they can lie in the lead space 817.

It is also, pointed out that the second leadframe 811 (although not specifically depicted here) can also comprise mold flow apertures (such as shown in detail in FIGS. 2(a) and 2(b)). Although not preferred, the inventors specifically contemplate such embodiments forming a part of the invention.

FIG. 10(a) is a figurative view of such a stack as viewed from the bottom, showing a first and second leadframes (810, 811) mounted on a jig in a suitable arrangement. The first leadframe 810 is mounted with the jig. In this embodiment, securement arm 128 is engaged with a complementary alignment peg 850 of a mounting jig. In this view, the contacts 814 of the first die are shown. In this view the raised portion of the first leadframe and the die are obscured from view by the presence of the pad 820. However, the first leadframe 810 securement features 128 are shown also engaged with the depicted mounting peg 850 of the jig. It is expressly pointed out that such securement can be accomplished by many other means and need not use pegs, not require the use of the same pegs to mount each leadframe, and can include many other configurations.

It should be pointed out that, in this embodiment, that the first leadframe 810 can include a raised (or lowered) portion 830 that enables the extension 829 of the second leadframe 811 to pass over (under) the securement feature 128 of the first leadframe 810. By using such a feature, one leadframe can be stacked on top of the other with no change in height in the final product. This is shown in the cross section view (as indicated by section line 840 of FIG. 10(a)) of FIG. 10(b). Thus, the die 801 is arranged between the first and second leadframes (810, 811, see FIG. 8) which are stacked over one another.

Additionally, once the two frames are mounted with the die, solder balls, and solder paste, they can all be subject to reflow to secure the structure together as a unit. Once in a unit, the whole can be encapsulated and then the tie bars can be severed during singulation to form completed two layer dual leadframe packages.

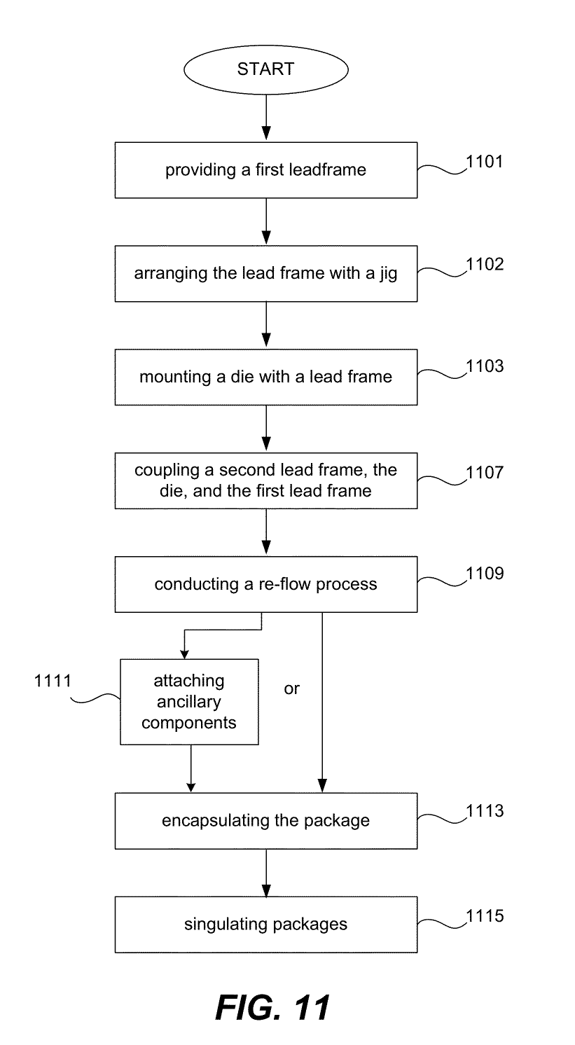

FIG. 11 expresses one process embodiment for forming such dual leadframe packages. The process begins by providing a first leadframe having an upset (raised) chip mounting pad (Step 1101). As before, this can be accomplished by stamping out the leadframes from a thin sheet of conductive material and then providing them for use. In one example, a 15 mil thick sheet of copper can be stamped or otherwise fabricated into an appropriate configuration using standard any of a number of processes known to those having ordinary skill in the art. As before, the first leadframe 810 has a raised chip mounting pad and a series of leads can be formed. For clarity, it is now stated that leads may include bonding pads, ground leads (optionally having a raised portion), and I/O leads (also optionally having a raised portion) and other structures. In most essentials the first leadframe 810 is substantially similar to that of leadframe 100 of FIG. 2(a). In this embodiment, the leadframe 810 can further include a raised portion that will enable the mounting of the second leadframe 811 such that the second leadframe 811 can lie upon a die (e.g, 801) without significant displacement due to the first leadframe. One example is shown in FIG. 10(b). Such a configuration can enable the placement of the second leadframe 811 on the die 801 without substantial bending.

Referring, for example, to FIG. 8, the first leadframe 810 will be arranged on a mounting jig (Step 1102) for further processing. As before, the securement features of the leadframe and the complementary alignment features of the jig are used to correctly position, and securely hold the leadframe in a desired orientation. Also, as before, the first leadframes are mounted as an array of a plurality leadframes that can be singulated later. It is contemplated that in some embodiments, the second leadframe can be mounted with the jig first or instead of the first leadframe discussed here.

One example embodiment of such a mounting process is illustrated and described with respect to FIG. 6(a) where a first leadframe 810 is arranged and aligned on mounting jig using the appropriate alignment and securement features. As before, the first leadframe 810 is mounted “upside down” on the jig.

The process continues by mounting an integrated circuit die (in this case die 801 or other electronic package) on a leadframe (Step 1103). Commonly, this will be the first leadframe (i.e., a top leadframe) but in alternative processes it can be another leadframe (e.g., a second or even a third leadframe). This can be accomplished by placing a plurality of solder balls 812 on a bottom surface of the raised portion of the first leadframe 810 (See, e.g., FIG. 8). As before, the balls interconnect the die 801 with the leads and other bonding surfaces of the leadframe 810. For example, the solder balls can be formed to interconnect with 110 leads, ground leads, heat flow paths and other surfaces of the leadframe. Typically, the solder balls will be placed on the ball attachment sites of the leadframe. As an alternative, the solder balls could be arranged on the die 801 and then paired up with first leadframe 810. For example, as before, using pick and place machines such as elsewhere described, as well other processes.

In general, using a first leadframe 810 with a raised die mounting surface, the die 801 is mounted with the top die surface facing toward, and electrically connected with, the leadframe 810. The combination of the die 801, solder balls 812, and leadframe 810 are then subject to reflow to mount the die 801 with the leadframe 810. As before, the height of the raised chip mounting pad can vary depending on the needs of the package design. However, in a preferred embodiment, the height of the raised chip mounting pad is such that when the die 801 is mounted (with the solder balls 812 or other electrically conductive interface materials) to the pad and subject to reflow, the bottom surface of the die is arranged such that a bottom surface of the second leadframe 813 lies substantially in the same plane as the bottom surfaces of the contacts 814 of the first leadframe 810.

At this point, the die 801, the first leadframe 810, and the solder calls 812 can be subject to reflow. However, it is generally preferable that the second leadframe 811 also be coupled with the die 801 prior to reflow. Thus, in a next step, in the depicted embodiment, the second leadframe 811 is coupled with the die 811 (Step 1107). For example, this can be facilitated by the application of a solder paste material 813 to a bottom surface of the die 812, and then the second leadframe 811 is mounted with the die 801. Again, the second leadframe 811 can include securement features (See, e.g., FIG. 9(a)) that can be coupled with alignment features of the jig (or elsewhere). Alternatively, the solder paste 813 can be applied to the second leadframe 811 and then mounted with the die 801. Of course, in some implementations solder paste 813 can be applied to the appropriate surfaces of both the die 810 and the second leadframe 811.

It is also specifically pointed out that the process can be altered. For example, rather than mounting the first leadframe 810 with the jig (Step 1107) the second leadframe 811 can be aligned and mounted on the jig first. Additionally, at least one of the die 801 and the second leadframe 811 can be a treated with solder paste 813 and then mated with the second leadframe 811. Such can be reflowed to join the two components. Additionally, it is pointed out that solder paste is not the only conductive mode of joining the second leadframe 811 with the die 801. In one such embodiment, ball bonds can be used as well as other such modes of mounting.

At this point the combined substrate can be subject to reflow (Step 1109) joining the components (801, 810, 811).

The dual level leadframe structure can now be subject to further process. In one embodiment, a determination is made whether further ancillary circuitry is to be added (e.g., such as those elements 426, 427 shown in FIG. 4(c) as well as others). Where such circuitry is to be added the ancillary circuit elements are added to the package (i.e., mounted with the first leadframe 810) (Step 1111).

Where, no added circuitry is added, the package is then treated with encapsulant material 805 to seal the die and ball bonds and portions of the leads (Step 1113). One embodiment of an encapsulated package is shown in FIG. 8 (which is substantially similar to that of FIG. 4(b)). In the depicted embodiment, the top portion of the leadframe is not encapsulated. Although analogues to those embodiments shown in FIGS. 4(a) and 4(c) are also generally formed in similar fashion as described with the single leadframe implementations described above. Additionally, one the ancillary circuitry is mounted the device package is then encapsulated (Step 1113).

It should be pointed out that the package substrates can be singulated into individual packages using die singulation process such as described above as well as other. The can remove the tie bars and also, punch processes can be used to segment the leadframes. For example, by applying a punching process, e.g., using an opening in the jig together with a punch tool, the hole in the jig can be arranged in alignment the arms 829 or portions of feature 128 such that punch through separates the leadframes.

Thus, to continue, after encapsulant is curing and hardening, the packages can be singulated (Step 1115). In many embodiments, the singulation process removes the temporary tie bars (and/or the securement features) to enable separate connection of the leads and also separation of the individual package devices. With this embodiment, packages looking as that shown in FIG. 7 can also be formed.

The present invention has been particularly shown and described with respect to certain preferred embodiments and specific features thereof. However, it should be noted that the above-described embodiments are intended to describe the principles of the invention, not limit its scope. Therefore, as is readily apparent to those of ordinary skill in the art, various changes and modifications in form and detail may be made without departing from the spirit and scope of the invention as set forth in the appended claims. Other embodiments and variations to the depicted embodiments will be apparent to those skilled in the art and may be made without departing from the spirit and scope of the invention as defined in the following claims. Further, reference in the claims to an element in the singular is not intended to mean “one and only one” unless explicitly stated, but rather, “one or more”. Furthermore, the embodiments illustratively disclosed herein can be practiced without any element which is not specifically disclosed herein. The inventors further indicate that, although process steps, method steps, algorithms or the like may be described in a sequential order, such processes, methods and algorithms may be configured to work in alternate orders. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the invention(s), and does not imply that the illustrated process is preferred.

We claim:

1. A leadframe for a semiconductor package, the leadframe comprising:
conductive lower and upper portions arranged such that the upper portion lies in an upper plane and defines a raised chip mounting pad and such that the lower portion includes in a lower contact plane arranged below the raised upper plane;
the raised chip mounting pad includes a plurality of ball attachment sites suitable for ball bonding with a semiconductor die; and
the lower portion comprising a set of leads that extend downward from the upper portion, with the leads configured such that a distal portion of the leads extends downward into the contact plane

2. The leadframe recited in claim 1 wherein the raised chip mounting pad is centrally located and where set of leads are arranged extending peripherally around the raised chip mounting pad.

3. The leadframe recited in claim 1 wherein raised chip mounting pad further comprises recessed moats proximal to the ball attachment sites configured to impede solder overflow from a ball attachment site during a ball bonding process.

4. The leadframe recited in claim 1 wherein the raised chip mounting pad is positioned above the contact plane a distance sufficient such that when a die is ball bonded to a bottom surface of the raised chip mounting pad a bottom surface of the die is substantially coplanar with the contact plane of the leadframe.

5. The leadframe recited in claim 1 wherein the raised chip mounting pad includes at least one opening configured to enable molding material to flow through the opening during a manufacturing process.

6. The leadframe recited in claim 1 wherein the leads extend outward from the raised chip mounting pad and include a downward bend directing distal ends of the leads into the contact plane.

7. An integrated circuit (IC) die package comprising:
a first leadframe comprising,
a raised chip mounting pad including a plurality of ball attachment sites arranged thereon, and
a set of leads extending away from the raised chip mounting pad said leads configured such that distal portions of the leads and not coplanar with the raised chip mounting pad and extend below the raised chip mounting pad;
a die having a top surface with a plurality of electrical connections formed thereon and a bottom surface with a die attachment pad formed thereon;
the die being coupled with the leadframe such that the plurality of electrical connections on the top surface of the die are electrically coupled with a bottom surface of the raised chip mounting pad with ball bonds coupled with ball attachment sites exposed on the bottom surface of the raised chip mounting pad and such that the die attachment pad faces downward; and
a mold envelope encapsulating the package with a molding material thereby encapsulating the die so that a bottom portion of the die attachment pad is exposed at a bottom portion of the encapsulated package and such that at least a portion of the distal ends of said leads is exposed outside the mold envelope.

8. The IC die package recited in claim 7 further comprising a second electrical device mounted on an upper surface of said raised chip mounting pad and arranged such that at least a portion of the second electrical device is enclosed by the mold envelope.

9. The IC die package recited in claim 8 wherein said second electrical device is ball bonded with the upper surface of said raised chip mounting pad.

10. The IC die package recited in claim 7 wherein the set of leads are arranged to extend peripherally away from a centrally positioned raised chip mounting pad and arranged such that a portion of the leads include a bent portion that directs the distal portion of the leads below the raised chip mounting pad.

11. The IC die package recited in claim 7 wherein the package further comprises,
a second leadframe having die bonding site, the second leadframe being arranged below the first leadframe and the die defining a thermal path from the die attach pad through the die bonding site; and
wherein the mold envelope is configured to expose a bottom surface of the die bonding site of the second leadframe.

12. The IC die package recited in claim 11 wherein the second leadframe comprises a die bonding site that is joined to the bottom of the die at the die attachment pad using solder paste.

13. The IC die package recited in claim 12 wherein the die bonding site enables function as a heat spreader and is not encapsulated by the mold material and exposed at a bottom surface of the package.

14. The IC die package recited in claim 11 wherein the raised chip mounting pad of the first leadframe comprises a ground connection tab that extends downward from the raised bonding pad into electrical contact with a portion of the second leadframe.

15. The IC die package recited in claim 11 wherein the first leadframe includes a first positioning feature and the second leadframe includes a second positioning feature wherein the first and second positioning features are arranged such that when the first and second leadframes are mounted on a positioning jig the first and second leadframes are in a correct alignment with each other.

16. A method of forming an integrated circuit (IC) die package, the method comprising:
providing a first leadframe with an upper portion that comprises a raised chip mounting pad and a set of leads extending away from the raised chip mounting pad;
mounting a semiconductor die with the raised chip mounting pad of the first leadframe using ball bonding; and
encapsulating the die and first leadframe in a mold envelope exposing at least a portion of the distal ends of the leads outside the mold envelope.

17. The method of claim 16 wherein:
mounting the die with the first leadframe is done such that ball attachment sites on a bottom surface of the raised chip mounting pad of the first leadframe are ball bonded with electrical contacts on the top of the die thereby establishing a plurality of electrical connections between the die and the first leadframe; and
encapsulating such that a bottom portion of the die is exposed at a bottom portion of the encapsulated package and such that at least a portion of the distal ends of said leads are exposed outside the mold envelope.

18. The method of forming an IC die package recited in claim 17 wherein the method further comprises,
providing a second leadframe having die bonding site; and
mounting the second leadframe underneath the die and under the first leadframe such that the die bonding site is joined to the bottom of the die.

19. The method of forming an IC die package recited in claim 18 wherein
providing of the first leadframe comprises providing a first leadframe that includes a first positioning feature;
providing of the second leadframe comprises providing a second leadframe that includes a second positioning feature;
providing a mounting tool that includes an alignment arrangement that engages with the first and the second positioning features;
mounting the first leadframe on the mounting tool such that the first positioning feature is aligned by the alignment arrangement of the tool; and
mounting the second leadframe on the mounting tool such that the second positioning feature is aligned by the alignment arrangement of the tool thereby aligning the first leadframe with the second leadframe wherein the die is mounted with one of the first leadframe and the second leadframe prior to the mounting of the other of the first and second leadframe being mounted with the tool.

20. The method of forming an IC die package recited in claim 18 wherein
said first leadframe further comprises a ground connection tab that extends downward from the raised chip mounting pad; and
said second leadframe further comprises a ground contact site;
and wherein said mounting of the second leadframe further includes electrically connecting the ground connection tab of the first leadframe with the ground contact site of the second leadframe.

21. The method of forming an IC die package recited in claim 17 further comprising
mounting another circuit element on the raised chip mounting pad of the first leadframe on a side opposite that of the semiconductor die.

22. The method of forming an IC die package recited in claim 21 wherein said encapsulating further comprises encapsulating at least a portion of the another circuit element.

23. The method of forming the IC recited in claim 17 wherein,
said providing the first leadframe comprises providing a plurality of first leadframes formed on a first leadframe substrate;
said providing the semiconductor die comprises providing a plurality of dice;
said mounting the die with the first leadframe comprises mounting one of said plurality of dice with an associated one of the first leadframes; and
said encapsulating comprises encapsulating each of the leadframes and the dice; and
further comprises singulating the encapsulated leadframes and dice to separate them into discrete IC packages.

24. The method of forming the IC recited in claim 23 further comprising
providing of plurality of second leadframes having formed thereon a plurality of die bonding sites;
mounting the second leadframe substrate under the dice and under the first leadframe substrate such that the first leadframe substrate, the dice, and the second leadframe substrate are all in desired alignment with each other; and
wherein said encapsulating encapsulates desired portions of the first and second leadframe substrates and dice; and
wherein said singulating the encapsulated leadframes and dice to separate them into discrete IC packages comprises singulating to form discrete IC packages that include said first leadframe, said die, and said second leadframe.
